(19) United States
(12) Patent Application Publication
(10) Pub. No.: US 2022/0138382 A1
(43) Pub. Date: May 5, 2022

(54) METHODS AND SYSTEMS FOR SIMULATING AND PREDICTING DYNAMICAL SYSTEMS WITH VECTOR-SYMBOLIC REPRESENTATIONS

(71) Applicant: APPLIED BRAIN RESEARCH INC., Waterloo (CA)

(72) Inventors: Aaron Russell VOELKER, Stittsville (CA); Christopher David ELIASMITH, Waterloo (CA); Peter BLOUW, Breslau (CA); Terrance STEWART, Waterloo (CA); NICOLE SANDRA-YAFFE DUMONT, Waterloo (CA)

(21) Appl. No.: 17/520,379

(22) Filed: Nov. 5, 2021

Related U.S. Application Data
(60) Provisional application No. 63/110,231, filed on Nov. 5, 2020.

(51) Int. Cl. G06F 30/27; G06F 30/17; G06N 3/04

(52) U.S. Cl. CPC G06F 30/27; G06N 3/049; G06F 30/17

(57) ABSTRACT

The present invention relates to methods and systems for simulating and predicting dynamical systems with vector symbolic representations of continuous spaces. More specifically, the present invention specifies methods for simulating and predicting such dynamics through the definition of temporal fractional binding, collection, and decoding subsystems that collectively function to both create vector symbolic representations of multi-object trajectories, and decode these representations to simulate or predict the future states of these trajectories. Systems composed of one or more of these temporal fractional binding, collection, and decoding subsystems are combined to simulate or predict the behavior of at least one dynamical system that involves the motion of at least one object.

### (1) FIELD OF THE INVENTION

The present invention generally relates to the field of simulating and predicting the behavior of dynamical systems, and more particularly to methods and systems for simulating and predicting such systems using vector symbolic representations.

### (2) BACKGROUND OF THE INVENTION

A considerable amount of recent progress in AI research has been driven by the fact that artificial neural networks are highly effective function approximators when trained with sufficient amounts of data. For example, neural networks have been used with great success when approximating functions from images to image labels, from audio waveforms to text labels, and from word sequences to topic labels. Neural networks can be applied to regression, classification, and density estimation tasks, and typically operate on vector valued inputs and outputs. There are, however, important aspects of intelligent behavior that are not naturally described by static functions applied to discrete vector-valued inputs. Many researchers accordingly recognize the need for new machine learning techniques that can enable neural network models to perform complex forms of reasoning using structured data. In particular, there is a need for extending neural networks to manipulate structured symbolic representations in task contexts that involve dynamics defined over continuous time and space.

Many existing approaches to modelling dynamical systems involve the use of recurrently connected neural networks that maintain an internal state representation that changes over time as new inputs are processed or new outputs are generated. For example, recurrent neural networks have been widely used to learn and model the dynamics of sales data, stock prices, vehicle movements, robotic actuators, and computer network traffic, amongst other things. However, in almost all such cases, the state of the dynamical system being modelled is represented as a vector in which each element corresponds to a discrete variable such as the sales volume of a particular product or the location of a particular vehicle, and changes to these elements reflect changes to the corresponding variable values.

An alternative approach to representing the state of a dynamical system involves the use of a ‘vector symbolic architecture’ (VSA) in which data elements are mapped to vectors in a high-dimensional space, and operations on these data elements are performed by an artificial neural network. However, existing VSAs are generally limited to performing discrete input-output transformations on vector representations of discrete data structures such as graphs, lists, or trees; such VSAs cannot be used to simulate and predict the behavior of arbitrary dynamical systems whose states are defined in terms of a combination of discrete and continuous data elements.

A number of different methods are disclosed in the prior art for both (a) defining structured representations that encode flexible combinations of continuous and discrete elements within the overall framework of a VSA, and (b) simulating dynamical systems using artificial neural networks. The following documents and patents are provided for their supportive teachings and are all incorporated by reference: Prior art document https://arxiv.org/abs/cs/0412059 introduces the concept of a VSA in which symbols are mapped to vectors in a high-dimensional space, and operations on the vectors are used to implement symbol processing. Prior art document http://www2.fiit.stuba/sk/˜kvasnicka/CognitiveScience/6.prednaska/plate.ieee95.pdf describes methods for creating VSA representations through the use. of circular convolution as a binding operator that associates vector representations of symbolic data with one another. Circular convolution is a compression operation that enables the creation of sequences of various lengths and simple frame like structures, all of which are represented in fixed width vector representations. Neither document discloses methods for representing continuous data within a VSA for the purpose of simulating or predicting the behavior of a dynamical system.

A further prior art document, https://patents.google.com/patent/US20140156577A1/en, discloses methods, systems, and an apparatus that provide for perceptual, cognitive, and motor behaviors in an integrated system implemented using neural architectures. Components of the system communicate using artificial neurons that implement neural networks. The connections between these networks form representations—referred to as ‘semantic pointers’—which model the various firing patterns of biological neural network connections. Semantic pointers can be thought of as elements of a neural vector space that support a variety of basic VSA operations.

Prior art document http://compneuro.uwaterloo.ca/files/publications/komer.2019.pdf discloses methods for creating ‘spatial semantic pointers’ (SSPs) that encode blends of continuous and discrete structures within the framework of a vector-symbolic architecture. SSPs can be used to generate and manipulate representations of spatial maps that encode the positions of multiple objects. These representations can be transformed to answer queries about the locations and identities of different objects, and change their relative or global positions, amongst other things. SSPs can be processed using spiking neural networks, and, as disclosed in prior art document https://uwspace.uwaterloo.ca/handle/10012/16430, can provide significant performance improvements across a range of machine learning tasks that involve continuous data. These prior art documents do not disclose how to use SSPs in the context of tasks that involve predicting or simulating the behavior of dynamical systems.

Prior art document https://arxiv.org/pdf/2110.05266.pdf describes benchmarks for evaluating the performance of neural networks at predicting the behavior of a range of chaotic dynamical systems. Results indicate that neural networks such as LSTMs and Transformers can do an adequate job on this task, but the dynamical systems being evaluated have only a handful of dimensions, ad do not combine discrete and continuous elements of sort required to represent many real-world task domains.

Finally, prior art document http://compneuor.uwaterloo.ca/files/publicaitons/voelker_2019_lmu.pdf describes a recurrent neural network architecture that couples one or more layers implementing a linear time-invariant (LTI) dynamical system with one or more non-linear layers to process sequential input data. The weights governing this LTI system are analytically derived to compute an optimal delay of an input signal over some temporal window, and the non-linear components of the network read from the state of this system to compute arbitrary functions of the data in the input window. The resulting network is called a “Legendre memory unit” (LMU) due to how the LTI system represents data using a Legendre basis, and experimental evidence indicates that the LMU can very accurately predict the future states of chaotic dynamical systems. Again, though, only low dimensional, continuous dynamical systems are evaluated in the context of this work, leaving it unclear how one might simulate and predict the behavior of dynamical systems that combine large number of continuous and discrete data elements of the sort encoded using vector-symbolic representations such as spatial semantic pointers.

The present application addresses the above-mentioned concerns and shortcomings with regard to providing methods and systems for simulating and predicting dynamical systems using vector symbolic representations. More specifically, the present application discloses methods and systems that exploit vector-symbolic representations to (1) simulate continuous trajectories involving multiple objects, (2) simulate interactions between these objects and walls, and (3) learn the dynamics governing these interactions in order to predict future object positions. Applications of these methods and systems can lead to more effective spatial navigation systems for aerial and ground-based vehicles, better predictions of the future states of multi-agent systems such as sports games or delivery driver fleets, and more effective control of robotic devices that interact with continuous environments containing discrete objects.

### (3) SUMMARY OF THE INVENTION

In the view of the foregoing limitations inherent in the known methods present in the prior art, the present invention provides methods and systems for simulating and predicting dynamical systems using vector symbolic representations. More specifically, the present invention introduces a method and system for simulating and predicting the behaviors of arbitrary dynamical systems using “spatial semantic pointers” (SSPs), which are a kind of vector-symbolic representation in which slot-filler bindings defined over spaces in which either or both slots and fillers can be separated by a continuous distance function. Subsystems that carry out binding, collection, and decoding with these continuous slot-filler structures can be applied to represent, simulate, and predict trajectories involving multiple objects moving through a continuous space of arbitrary dimensionality. As such, the general purpose of the present invention, which will be described subsequently in greater detail, is to provide methods and systems for simulating and predicting the behavior of dynamical systems in which one or more objects follow a trajectory through a continuous space of arbitrary dimensionality. Crucially the objects and their trajectories are jointly represented.

The main aspect of the present invention is to provide methods and systems for simulating and predicting dynamical systems using vector-symbolic representations. The methods consist of defining at least one temporal fractional binding subsystem that takes a high-dimensional vector representation that jointly represents at least one object and its spatial location, rotates the vector representation to associate it with a particular point in time, and returns this rotated vector representation as output. The methods further consist of defining a collection subsystem that combines the outputs of a temporal fractional binding subsystem through summation or concatenation to produce a representation of the spatial location of at least one object over multiple points in time. A decoding subsystem is then defined that takes a representation produced by the collection subsystem and generates a trajectory corresponding to the motion of at least one object; input vector representations are used to propagate activity through the temporal fractional binding, collection, and decoding subsystems to simulate or predict the behavior of at least one dynamical system involving the motion of at least one object over time.

In an exemplary embodiment of the invention, there is disclosed a system for encoding and decoding representations of continuous trajectories involving one or more objects moving through a two-dimensional space. These representations are produced by applying a temporal fractional binding subsystem to a sequence of input representations corresponding to the positions of the objects at different points in time. A collection subsystem is then used to combine the resulting output of the temporal fractional binding subsystem into a single representation summarizing the input history. This representation is provided, finally, to a decoding subsystem that processes it in order to regenerate the encoded trajectory.

In another exemplary embodiment of the invention, there is disclosed a system that predicts the future behavior of a dynamical system whose state is represented as a spatial semantic pointer. The system use takes one or more spatial semantic pointer representations corresponding to the history or initial state of a dynamical system, and then passes these representations to a decoding subsystem that predicts one or more spatial semantic pointer representations corresponding to the future state of the dynamical system. In one variant of the exemplary embodiment, the decoding subsystem is implemented as a Legendre Memory Unit recurrent neural network, and the dynamical system whose future is being predicted represents the position of a ball bouncing between four enclosing walls on a two-dimensional plane. In another variant of the exemplary embodiment, the decoding subsystem is implemented as a feedforward neural network, and the dynamical system whose future is being predicted represents the position of multiple objects moving around an unobstructed two dimensional plane. The feedforward neural network may be trained via gradient descent or implement a fixed set of algebraic manipulations on the set of spatial semantic pointers.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

These together with other objects of the invention, along with the various features of novelty which characterize the invention, are pointed out with particularity in the disclosure. For a better understanding of the invention, its operating advantages and the specific objects attained by its uses, reference should be had to the accompanying drawings and descriptive matter in which there are illustrated preferred embodiments of the invention.

### (4) BRIEF DESCRIPTION OF THE DRAWINGS

The invention will be better understood and objects other than those set forth above will become apparent when consideration is given to the following detailed description thereof. Such description makes reference to the annexed drawings wherein:

FIG. 1 is an illustration of a simulating a dynamical system in which if a single object, represented with a spatial semantic pointer, oscillates in a circular pattern across a two-dimensional plane;

FIG. 2 is an illustration of the accuracy of different variants of the systems and methods disclosed herein for simulating and predicting dynamical system with vector symbolic representations; and

FIG. 3 is an illustration of predicting a dynamical system in which a single object, represented with a spatial semantic pointer, bounces between four walls enclosing a two-dimensional plane.

### (5) DETAILED DESCRIPTION OF THE INVENTION

In the following detailed description, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that the embodiments may be combined, or that other embodiments may be utilized and that structural and logical changes may be made without departing from the spirit and scope of the present invention. The following detailed description is, therefore, not to be taken in a limiting sense, and the scope of the present invention is defined by the appended claims and their equivalents.

The present invention is described in brief with reference to the accompanying drawings. Now, refer in more detail to the exemplary drawings for the purposes of illustrating non-limiting embodiments of the present invention.

As used herein, the term “comprising” and its derivatives including “comprises” and “comprise” include each of the stated integers or elements but does not exclude the inclusion of one or more further integers or elements.

As used herein, the singular forms “a”, “an”, and “the” include plural referents unless the context clearly dictates otherwise. For example, reference to “a device” encompasses a single device as well as two or more devices, and the like.

As used herein, the terms “for example”, “like”, “such as”, or “including” are meant to introduce examples that further clarify more general subject matter. Unless otherwise specified, these examples are provided only as an aid for understanding the applications illustrated in the present disclosure, and are not meant to be limiting in any fashion.

As used herein, the terms “may”, “can”, “could”, or “might” be included or have a characteristic, that particular component or feature is not required to be included or have the characteristic.

Exemplary embodiments will now be described more fully hereinafter with reference to the accompanying drawings, in which exemplary embodiments are shown. These exemplary embodiments are provided only for illustrative purposes and so that this disclosure will be thorough and complete and will fully convey the scope of the invention to those of ordinary skill in the art. The invention disclosed may, however, be embodied in many different forms and should not be construed as limited to the embodiments set forth herein.

Various modifications will be readily apparent to persons skilled in the art. The general principles defined herein may be applied to other embodiments and applications without departing from the spirit and scope of the invention. Moreover, all statements herein reciting embodiments of the invention, as well as specific examples thereof, are intended to encompass both structural and functional equivalents thereof. Additionally, it is intended that such equivalents include both currently known equivalents as well as equivalents developed in the future (i.e., any elements developed that perform the same function, regardless of structure). Also, the terminology and phraseology used is for the purpose of describing exemplary embodiments and should not be considered limiting. Thus, the present invention is to be accorded the widest scope encompassing numerous alternatives, modifications and equivalents consistent with the principles and features disclosed. For clarity, details relating to technical material that is known in the technical fields related to the invention have not been described in detail so as not to unnecessarily obscure the present invention.

Thus, for example, it will be appreciated by those of ordinary skill in the art that the diagrams, schematics, illustrations, and the like represent conceptual views or processes illustrating systems and methods embodying this invention. The functions of the various elements shown in the figures may be provided through the use of dedicated hardware as well as hardware capable of executing associated software. Similarly, any switches shown in the figures are conceptual only. Their function may be carried out through the operation of program logic, through dedicated logic, through the interaction of program control and dedicated logic, or even manually, the particular technique being selectable by the entity implementing this invention. Those of ordinary skill in the art further understand that the exemplary hardware, software, processes, methods, and/or operating systems described herein are for illustrative purposes and, thus, are not intended to be limited to any particular named element.

Each of the appended claims defines a separate invention, which for infringement purposes is recognized as including equivalents to the various elements or limitations specified in the claims. Depending on the context, all references below to the “invention” may in some cases refer to certain specific embodiments only. In other cases it will be recognized that references to the “invention” will refer to subject matter recited in one or more, but not necessarily all, of the claims.

All methods described herein can be performed in any suitable order unless otherwise indicated herein or otherwise clearly contradicted by context. The use of any and all examples, or exemplary language (e.g., “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Various terms as used herein are shown below. To the extent a term used in a claim is not defined below, it should be given the broadest definition persons in the pertinent art have given that term as reflected in printed publications and issued patents at the time of filing.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all groups used in the appended claims.

For simplicity and clarity of illustration, numerous specific details are set forth in order to provide a thorough understanding of the exemplary embodiments described herein. However, it will be understood by those of ordinary skill in the art that the embodiments described herein may be practiced without these specific details. In other instances, well-known methods, procedures and components have not been described in detail so as not to obscure the embodiments generally described herein.

Furthermore, this description is not to be considered as limiting the scope of the embodiments described herein in any way, but rather as merely describing the implementation of various embodiments as described.

The embodiments of the digital circuits described herein may be implemented in configurable hardware (i.e. FPGA) or custom hardware (i.e. ASIC), or a combination of both with at least one interface. The input signal is consumed by the digital circuits to perform the functions described herein and to generate the output signal. The output signal is provided to one or more adjacent or surrounding systems or devices in a known fashion.

As used herein the term ‘node’ in the context of an artificial neural network refers to a basic processing element that implements the functionality of a simulated ‘neuron’, which may be a spiking neuron, a continuous rate neuron, or an arbitrary linear or non-linear component used to make up a distributed system.

The described systems can be implemented using adaptive or non-adaptive components. The system can be efficiently implemented on a wide variety of distributed systems that include a large number of non-linear components whose individual outputs can be combined together to implement certain aspects of the system as will be described more fully herein below.

The main embodiment of the present invention is to provide a set of methods and systems for simulating and predicting dynamical systems using vector symbolic representations. More specifically, the present invention introduces methods and systems for simulating and predicting the behaviors of arbitrary dynamical systems using “spatial semantic pointers” (SSPs), which are a kind of vector-symbolic representation in which slot-filler bindings defined over spaces in which either or both slots and fillers can be separated by a continuous distance function. Subsystems that carry out binding, collection, and decoding with these continuous slot-filler structures can be applied to represent, simulate, and predict trajectories involving multiple objects moving through a continuous space of arbitrary dimensionality over time. As such, the general purpose of the present invention is use vector-symbolic representations to (1) simulate continuous trajectories involving multiple objects, (2) simulate interactions between these objects and various obstacles, and (3) learn the dynamics governing these interactions in order to predict future object positions.

The term ‘vector space’ here refers to a set of vectors that have addition and scalar multiplication operations defined over them. The term ‘slot’ here refers to a variable in a data structure that can take on different values, while the term ‘filler’ refers to a value in a data structure that different variables might store. A ‘slot-filler’ pair here refers to a data structure element consisting of a variable and its corresponding value. The term ‘binding operator’ here refers to a mathematical operator that defines a function that maps two input vectors to a single output vector that represents the pairing of the two input vectors. The inputs to a binding operator may correspond to a slot and a filler in a data structure, and the output of a binding may thereby correspond to a slot-filler pair in said data structure. Circular convolution is an example of a binding operator. The term ‘unbinding operator’ here refers to a mathematical operator that defines a function that maps two vector inputs to a single vector output, where one of the input vectors represents a slot-filler pair, the other input vector represents the slot (or filler), and the output vector represents the correspond filler (or slot). Circular correlation (i.e., deconvolution) is an example of an unbinding operator. Binding and unbinding operators are either approximate or exact inverses of one another. The term ‘inverse vector’ here refers to a vector that undoes the effect of a binding operator when bound with the output of this operator.

The term ‘non-fractional binding’ here refers to the use of a binding operator to bind a vector representation to itself some integer number of times. To explain, if k is a natural number, BϵR^{d} is a fixed d-dimensional vector, and \textcircled{*} is a binding operator, then a non-fractional binding of B to itself k−1 times is:

B^{k}=B\textcircled{*}B\textcircled{*}B . . . \textcircled{*}B

where B occurs on the right-hand side of the equation k times. The term ‘fractional binding’ here refers to the use of a binding operator to bind a vector representation to itself some fractional number of times. By analogy to fractional powers defining the multiplication of the real numbers, if k in the equation above is instead a real number, then B^{k} encodes a continuous quantity. Assuming that the operator \textcircled{*} is circular convolution, then a fractional binding is defined by expressing the equation in the complex domain:

B^{k}=F⁻¹{F{B}^{k}},kϵR

where F{⋅} is the Fourier transform, and F{B}^{k} is an element-wise exponentiation of a complex vector. In essence, fractional binding is to a binding operator as exponentiation is to multiplication.

The term ‘unitary vector’ here refers to a representation within a vector symbolic architecture that has a L2-norm of exactly 1 and Fourier coefficients whose magnitudes are also exactly 1. Importantly, these properties ensure that (1) the dot product between two unitary vectors becomes identical to their cosine similarity, and (2) binding one unitary vector with another unitary vector results in yet another unitary vector; hence, unitary vectors are “closed” under binding with circular convolution. The term ‘rotation’ here refers to an operation on a vector that modifies its elements without changing its L2 norm. Binding one or more unitary vectors to another unitary vector implements a rotation of the former vectors that is defined by the latter vector.

The term ‘spatial semantic pointer’ here refers to a vector symbolic representation that uses fractional binding to link representations of objects to representations of locations in continuous spaces corresponding to points, lines, planes, volumes, or spans of time. In general, a spatial semantic pointer can be used to represent points in Rⁿ by repeating fractional binding as defined above in the Fourier domain n times, using a different base vector B for each represented dimension (i.e., for each axis). For an encoding of a point in a two-dimensional plane, n=2, and the vector representation the point's (x, y) coordinates is defined as:

S(x,y)=X^{x}\textcircled{*}Y^{y}

where X and Y are vector representations, x and y are reals, exponentiation indicates fractional binding, and \textcircled{*} indicates non-fractional binding. Spatial semantic pointer representations may correspond to a plurality of data structures and a plurality of human-interpretable data types. The plurality of data structures may include planes, volumes, images, and time-series. The plurality of human-interpretable data types may include maps, scenes, sounds, and images.

For example, to represent a discrete object occupying some point or region in a continuous space using SSPs, non-fractional binding is performed to associate a vector representation of the object to an SSP representation of a point as follows:

M=OBJECT\textcircled{*}X^{x}\textcircled{*}Y^{y}

where M is a ‘memory’ SSP that stores the location of the object in the continuous space as defined by S. It is possible to represent sets of m labelled objects in the same memory using superposition or vector addition:

$$M = {\sum }_{i = 1}^{m} {OBJECT}_{i} {X}^{{x}_{i }} {Y}^{{y}_{i}}$$

It is possible to then using an unbinding operator to determine which object is represented at a point (x, y) as follows:

M\textcircled{*}(X^{x}^{ᵢ}\textcircled{*}^{y}^{ᵢ})⁻¹=M\textcircled{*}X^{-x}^{ᵢ}\textcircled{*}Y^{-y}^{ᵢ}≈OBJECTᵢ

By the properties of binding and superposition, the resulting vector will have the highest cosine similarity with the representation of the object located at point (x, y). Representations of objects and the continuous spaces they occupy may each be structured to an arbitrary degree of complexity, in the sense of consisting of combinations of simple and complex representations. Simple representations in the present invention are random unit-length vectors of dimension d, which ensures that the vector components are identically distributed, and that all of the vectors are approximately orthogonal to one another. Complex representations include some number of simple representations as constituent parts.

The term ‘temporal fractional binding subsystem’ here refers to a computer implemented subsystem that takes one or more spatial semantic pointers as input, and uses fractional binding to rotate these semantic pointers using unitary vector T that represents a time axis. The rotated semantic pointers are produced as outputs of the system, and represent the scene encoded by a particular SSP occurring at a particular time. For example, if an input semantic pointer encoded the location of a single object, and is processed by a temporal fractional binding subsystem at time t, then the output of the subsystem would be a vector symbolic representation that can formally described as follows:

P(x,y,t)=OBJECT\textcircled{*}T^{t}\textcircled{*}X^{x}\textcircled{*}Y^{y}

where x and y are the coordinates of the object encoded by the SSP, t is the time at which the SSP is encoded by the subsystem, and P is the output of the subsystem.

The term ‘collection subsystem’ here refers to a computer implemented subsystem that combines the outputs of a temporal fractional binding subsystem to produce a single vector symbolic representation that summarizes the history of these outputs. Outputs are combined by the collection subsystem via vector summation, vector concatenation, or any other mathematical operation that maps from some number of vector-valued inputs to a single output. In the case where summation is implemented by a collection subsystem, a single encoding of a trajectory of SSPs processed by a temporal fractional binding subsystem would be produced as follows:

Trajectory=Σᵢ₌ᵢ^{m}OBJECT\textcircled{*}T^{t}^{ᵢ}\textcircled{*}X^{x}^{ᵢ}\textcircled{*}Y^{y}^{ᵢ}

where m is the number is the number of time points in the trajectory, i ranges over these timepoints, and tᵢ indicates the relative time of the ith point within the trajectory. Encodings of continuous trajectories can produced by replacing summation with integration as follows:

Trajectory=∫₀^{t}OBJECT \textcircled{*}T^{τ}\textcircled{*}S(τ)dτ

where S(τ) produces the encoding for each point within some trajectory of points defined over a continuous interval of time, τ∈[0, t].

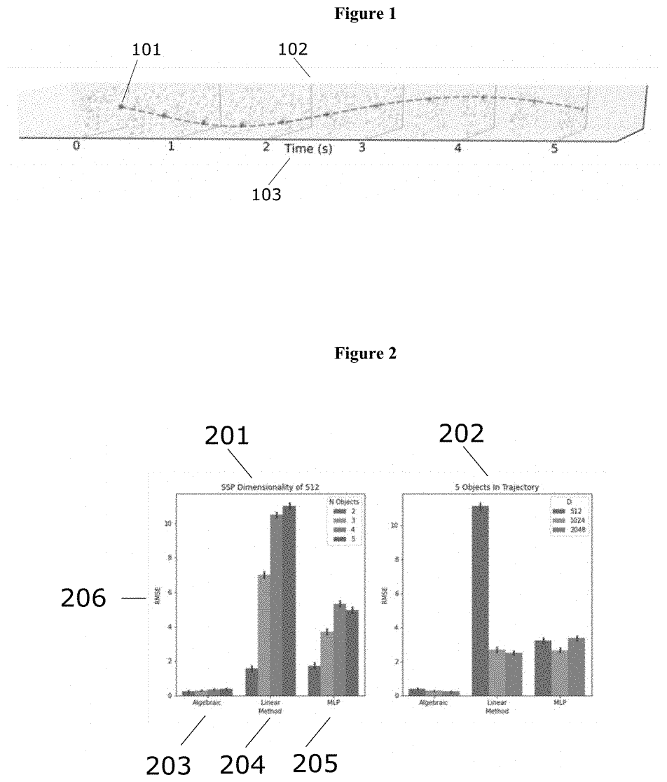

The term ‘decoding subsystem’ here refers to a computer implemented subsystem that takes in either a trajectory representation produced by the collection subsystem, or one or more SSPs, and produces a sequence of SSP outputs corresponding to the trajectory of a dynamical system. Referring to FIG. 1, a trajectory encoding of the sort just defined is passed through a decoding subsystem to produce a sequence of SSPs that each encode the position of an object oscillating in circular motion [101] over a two-dimensional plane [102] at different points in time [103]. Mathematically, each of the points is extracted from the trajectory encoding by applying an unbinding operator that extracts the SSP corresponding to a particular time point as follows:

Trajectory\textcircled{*}˜T^{t}^{ᵢ}≈OBJECT\textcircled{*}X^{x}^{ᵢ}\textcircled{*}Y^{y}^{ᵢ}

where the ˜ symbol produces an inverse vector as defined above.

In the case where a single SSP is provided as input to a decoding subsystem, the subsystem can simulate dynamical systems defined by both continuous-time and discrete-time differential equations through the application of binding operators to the SSP. In the discrete-time case with an SSP encoding a single object, the application of these operators takes the following form:

M_{t+Δt}=(X^{Δx}^{ₜ}\textcircled{*}Y^{Δy}^{ₜ})\textcircled{*}Mₜ=S(Δxₜ,Δyₜ)\textcircled{*}Mₜ

where Δxₜ and Δyₜ are derived from differential equations that relate x and y to t in some way. For example, if the underlying dynamics are linear, we have

$$•Δ x = \frac{d x}{d t} Δ t .$$

In the continuous-time case, the application of the operators takes a different form:

$$\frac{d M}{d t} = ( \frac{d x}{d t} ln X + \frac{d y}{d t} ln Y ) M$$

where ln is used to denote the principal branch of the matrix logarithm. It is also possible to impose collision dynamics whenever the simulated trajectory of a represented object encounters a solid surface (e.g., a floor or a wall). Specifically, the instantaneous velocity imposed by a given transformation is inverted and scaled on impact with a surface in accordance with a simple model of the physics of elastic collisions.

The above equations for simulating discrete-time dynamics with a decoding subsystem can also be extended to handle dynamical systems involving multiple objects. For example, one can tag each object's spatial coordinates with a representation of the object and then apply algebraic operators to update the position of all objects independently as follows:

M←M\textcircled{*}OBJECTᵢ\textcircled{*}(X^{x}^{ᵢ}^{+Δx}^{ᵢ}\textcircled{*}Y^{y}^{ᵢ}^{Δy}^{ᵢ}−ƒ(M\textcircled{*}OBJECTᵢ⁻¹))

where ƒ is a function that takes the noisy result of unbinding an object from an SSP as input and outputs a “clean” SSP. A sequence of such updates will independently modify all of the object positions represented in M so as to update the state of the underlying dynamical system. An alternative to simulating discrete-time dynamics with a decoding subsystem involves training an artificial neural network to approximate a function that repeatedly transforms an SSP by mapping it to a new SSP corresponding to the next point along some trajectory:

M←g(M,ΔM)

where g is a feedforward neural network or a linear transformation and:

ΔM=Σᵢ₌₁^{m}OBJECTᵢ\textcircled{*}X^{Δx}^{ᵢ}\textcircled{*}Y^{Δy}^{ᵢ}

Referring to FIG. 2, it is possible to compare the effectiveness of using algebraic operators and learned function approximators in a decoding subsystem while simulating dynamical systems. By varying the number of encoded objects while holding the dimensionality of the SSPs fixed [201], and varying the dimensionality of the SSPs while holding the number of encoded objects fixed [202], thorough comparisons between the use of algebraic operators [203], linear neural networks [204], and non-linear multi-layer perceptron (MLP) networks [205] are obtained for a root mean-squared error measure [206]. The linear model and MLP perform adequately on small training sets but do not generalize to the test data, while the model that uses algebraic operators performs very well on both training and test data.

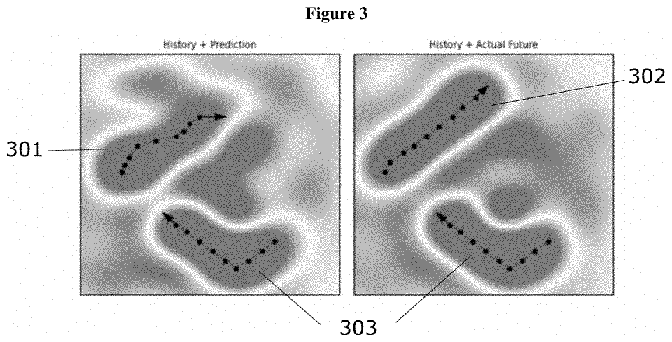

While a decoding subsystem can be used to simulate a dynamical system and thereby perform prediction, it is possible to perform prediction without an explicit representation of the underlying system dynamics by training a network to output a prediction of the future state of a moving object. For example, we can use SSP representations with a decoding subsystem to enable predictions of the future states of a bouncing ball in a square environment. Specifically, if a collection subsystem concatenates a number of SSP input representations corresponding to the past positions of the ball, then this set of representations can provided as input to recurrent neural network, such as a Legendre Memory Unit, that is trained to map from this history of ball positions to one or more future ball positions. Referring to FIG. 3, the predictions [301] of a trained LMU that uses 4 seconds of history [303] are compared to the ground truth positions [302] of a bouncing ball up to 6 seconds into the future. The network is trained on 4000s of bouncing dynamics within a 1 by 1 box. The training data are a time series of SSPs encoding the ball's position at 0.4 s intervals. The ball's trajectory is generated by a simulation with random initial conditions (position within the box and velocity) and the dynamics of boundary collisions. In the example simulation of FIG. 3, it is clear that an LMU-based decoding subsystem is able to accurately represent sliding windows of the ball's history while simultaneously predicting the sliding window of its future.

The individual computing elements within each of the subsystems of the disclosed invention can vary. Optionally they may be artificial neurons. Such computing elements or input representations may transmit a constant value, and are thereby non-spiking. Sometimes the computing elements emit occasional pulses in a manner determined by their input, and are thereby spiking. Spiking elements may be artificial neurons. Spiking versions of such neural networks are in some cases implemented using conventional computers via software that emulates the process by which a neuron input triggers a spike. In other cases, the neural networks are implemented using neuromorphic hardware that physically instantiates spike-based communication between computing elements.

The simulation and prediction of dynamical systems enabled by the present invention can involve arbitrary sequences of computations performed by temporal fractional binding subsystems, collection subsystems, and decoding subsystems. The same subsystems may be used repeatedly by communicating the outputs of one subsystem to the input of another subsystem in arbitrary sequential order. Optionally, multiple networks may be subsystems to one another in arbitrary sequential order.

The disclosed method for simulating and predicting dynamical systems using vector symbolic representations includes the following steps:
a. defining a temporal fractional binding subsystem that takes a high-dimensional vector representation that jointly represents at least one object and its spatial location, rotates the vector representation to associate it with a particular point in time, and returns this rotated vector representation as output;
b. defining a collection subsystem that combines the outputs of a temporal fractional binding subsystem through summation or concatenation to produce a representation of the spatial location of the at least one object over multiple points in time;
c. defining a decoding subsystem that takes a representation produced by the collection subsystem generates a trajectory corresponding to the motion of the at least one object; and
d. providing input vector representations that propagate activity through the temporal fractional binding, collection, and decoding subsystems to simulate at least one dynamical system involving the motion of the at least one object.

It is to be understood that the above description is intended to be illustrative, and not restrictive. For example, the above-discussed embodiments may be used in combination with each other. Many other embodiments will be apparent to those of skill in the art upon reviewing the above description.

The benefits and advantages which may be provided by the present invention have been described above with regard to specific embodiments. These benefits and advantages, and any elements or limitations that may cause them to occur or to become more pronounced are not to be construed as critical, required, or essential features of any or all of the embodiments.

While the present invention has been described with reference to particular embodiments, it should be understood that the embodiments are illustrative and that the scope of the invention is not limited to these embodiments. Many variations, modifications, additions and improvements to the embodiments described above are possible. It is contemplated that these variations, modifications, additions and improvements fall within the scope of the invention.

1. A method for simulating dynamical systems with high-dimensional vector representations, comprising:
a. defining one or more temporal fractional binding subsystem that takes a high-dimensional vector representation that jointly represents at least one object and its spatial location, rotates the high-dimensional vector representation to associate it with a particular point in time, and returns this rotated vector representation as output;
b. defining a collection subsystem that combines the outputs of the one or more temporal fractional binding subsystems through summation or concatenation to produce a representation of the spatial location of the at least one object over multiple points in time;
c. defining a decoding subsystem that takes the representation produced by the collection subsystem and generates a trajectory corresponding to the motion of the at least one object; and
d. providing input vector representations that propagate activity through the temporal fractional binding, collection, and decoding subsystems to simulate at least one dynamical system involving the motion of the at least one object.

2. The method according to claim 1, wherein the temporal fractional binding subsystem computes the circular convolution of its input with a unitary vector to apply a rotation.

3. The method according to claim 1, wherein the decoding subsystem generates each successive point in an output trajectory by computing the circular convolution of its input with a unitary vector.

4. The method according to claim 1, wherein at least one of the temporal fractional binding subsystems, the collection subsystem, and the decoding subsystem is implemented as an artificial neural network.

5. The method according to claim 1, wherein the decoding subsystem is directly provided with a vector representation of the spatial location of at least one object, and transforms this representation so as to model one or more differential equations that relate the spatial location of the at least one object to time.

6. The method according to claim 5, wherein the differential equations being modelled are defined with respect to either discrete time or continuous time.

7. The method according to claim 5, wherein the differential equations being modelled account for physical phenomena including gravitational forces, elastic or inelastic collisions, and friction.

8. The method according to claim 1, wherein the decoding subsystem is an artificial neural network, is directly provided with a vector representation of the spatial location of at least one object, and is trained via gradient descent to update the position of the at least one object so as to simulate its motion along an arbitrary trajectory.

9. The method according to claim 6, wherein the decoding subsystem is directly provided with a vector representation of the spatial location of at least one object along with a vector representation of the velocity of the at least object, and updates the position of the at least one object so as to simulate the motion trajectory defined by the vector representation of its velocity.

10. The method according to claim 6, wherein the decoding subsystem is directly provided with a vector representation of the spatial location of at least one object and is trained via gradient descent to update the position of the at least one object so as to predict its motion for an arbitrary amount of time into the future.

11. The method according to claim 1, wherein the decoding subsystem is a recurrent neural network that takes in a concatenated representation of the spatial location of at least one object over multiple points in time, and the recurrent neural network is trained to predict the next spatial location of the at least one object.

12. The method according to claim 1, wherein the temporal fractional binding subsystem takes in a vector representation of a data structure containing an arbitrary number of continuous and discrete data elements, and the decoding subsystem simulates at least one dynamical system whose state is defined with respect to these data elements.

13. The method according to claim 1, wherein the collection subsystem implements continuous integration to produce an output representation and the decoding subsystem generates a continuous trajectory from this output representation.

14. A system for simulating dynamical systems with high-dimensional vector representations comprising:
a. at least one temporal fractional binding subsystem that takes a high-dimensional vector representation that jointly represents at least one object and its spatial location, rotates the vector representation to associate it with a particular point in time, and returns this rotated vector representation as output;
b. a collection subsystem that combines the outputs of the at least one temporal fractional binding subsystem through summation or concatenation to produce a representation of the spatial location of the at least one object over multiple points in time;
c. a decoding subsystem that takes a representation produced by the collection subsystem and generates a trajectory corresponding to the motion of at the least one object; and
d. input vector representations that propagate activity through the temporal fractional binding, collection, and decoding subsystems to simulate at least one dynamical system involving the motion of at the least one object.
